(19) United States
(12) Patent Application Publication
(10) Pub. No.: US 2012/0248942 A1
(43) Pub. Date: Oct. 4, 2012

(54) ELECTROMECHANICAL CONVERTER, METHOD FOR ITS PRODUCTION AND USE THEREOF

(75) Inventors: Silmon James Biggs, Los Gatos, CA (US); Joachim Wagner, Koln (DE); Werner Jenninger, Koln (DE); Julia Hitzbleck, Koln (DE)

(73) Assignees: Bayer MaterialScience AG, Leverkusen (DE); Artificial Muscle, Inc., Sunnyvale, CA (US)

(21) Appl. No.: 13/078,257

(22) Filed: Apr. 1, 2011

(51) Int. Cl. H01L 41/047; H05K 13/00; H01L 41/16

(52) U.S. Cl. 310/363; 310/365; 29/592.1

(57) ABSTRACT

An electromechanical converter comprises a dielectric elastomer layer (1) designed as one piece and having a first side and a second side opposite the first side. The first and the second side of the dielectric elastomer layer (1) are corrugated in the same direction as each other with the formation of ridges (2) and furrows (3). The dielectric elastomer layer (1) comprises a polyurethane polymer, the first side of the dielectric elastomer layer (1) being in contact with a first electrode (4) and the second side of the dielectric elastomer layer (1) being in contact with a second electrode (5) and the first and second electrode (4, 5) having a same-directional corrugated design corresponding to the first and second side of the dielectric elastomer layer (1).

The present invention relates to an electromechanical converter. It also relates to a method for its production and the use thereof.

Electromechanical converters convert electrical energy into mechanical energy and vice versa. They can be used as a component in sensors, actuators and generators. WO 2001/06575 A1, for example, discloses an energy converter, its use and its production. The energy converter converts mechanical energy into electrical energy. Some of the energy converters shown contain prestressed polymers. Prestressing improves the conversion between electrical and mechanical energy. A device is also disclosed which comprises an electrically active polymer for converting electrical energy into mechanical energy. Furthermore, electrodes are disclosed which are adapted to the shape of the polymer in the energy converter. Methods for producing an electromechanical device comprising one or more electrically active polymers are also disclosed.

When the dielectric elastomer is extended, it is desirable for the electrodes in contact with the elastomer to be able to follow this extension. In the case of flat elastomer layers this requirement generally calls for extensible electrode designs or electrode materials. Structured elastomer surfaces have been proposed as a way out of this restriction.

Laminar composites consisting of dielectric elastomers and other materials for electromechanical converters are disclosed in US 2009/0169829 A1. This patent application is concerned with a multilayer composite comprising a film, a first electrically conductive layer and at least one interlayer arranged between the film and the first electrically conductive layer. The film is made from a dielectric material and has a first and second surface. At least the first surface includes a surface pattern comprising ridges and furrows. The first electrically conductive layer is applied on top of the surface pattern and has a corrugated shape formed by the surface pattern of the film.

According to an embodiment of the invention described in this patent application the interlayer can be obtained by plasma treatment of the film surface. The interlayer serves to improve the adhesion between the electrically conductive layer and the film.

DE 100 54 247 A1 describes an actuating element comprising a body made from an elastomer material provided with an electrode on each of two opposing lateral faces. The objective is to improve the dynamics. To this end at least one lateral face has at least one corrugated region comprising peaks and troughs running parallel to the transverse direction as extrema, said region being covered by an electrode which covers the entire surface of at least part of the extrema and adheres to the corrugated region.

US 2009/072658 A1 discloses a film consisting of a dielectric material having a first surface and a second surface, wherein at least the first surface comprises a surface pattern consisting of raised and depressed surface sections. A first electrically conductive layer is positioned on top of the surface pattern and the electrically conductive layer has a corrugated shape formed by the surface pattern of the film. The second surface is substantially flat.

If both sides of a dielectric elastomer film are not corrugated, then extension leads to relative variations in the film thickness. This is, however, undesirable.

US 2005/104145 A1 discloses dielectric actuators of the type in which the electrostatic force of attraction between two electrodes positioned on an elastomeric body leads to a compression of the body in a first direction and a corresponding extension of the body in a second direction. The dielectric actuator/sensor structure consists of a first sheet of an elastomeric material having at least one smooth surface and a second surface and a second sheet of an elastomeric material having at least one smooth surface and a second surface. The sheets are laminated together so that their second surfaces are exposed. A first electrode is provided on the second surface of the first sheet and a second electrode on the second surface of the second sheet.

A disadvantage of the solution of laminating a plurality of layers of a dielectric elastomer film together as proposed in the prior art is the elevated production complexity associated with the additionally required steps. There is also a risk of an unwanted rigidity being introduced into the system at the interface between two films laminated on top of one another.

The object underlying the present invention is to provide an electromechanical converter of the type described in the introduction which offers the possibility of also using conventionally unsuitable non-extensible or poorly extensible electrode materials and which is simple to produce.

The object is achieved according to the invention in that the converter comprises a dielectric elastomer layer designed as one piece and having a first side and a second side opposite the first side, the first and the second side of the dielectric elastomer layer having a corrugated design with the formation of ridges and furrows, the dielectric elastomer layer comprising a polyurethane polymer, the first side of the dielectric elastomer layer being in contact with a first electrode and the second side of the dielectric elastomer being in contact with a second electrode, and the first and second electrode having a corrugated design corresponding to the first and second side of the dielectric elastomer layer.

Through the choice of the polyurethane material it is possible to produce one-piece corrugated dielectric elastomer layers in a simple manner. Suitable methods are for example blow moulding, extrusion, reaction extrusion or reaction injection moulding. The corrugated elastomer layers can then be provided with electrodes and leave sufficient scope for extension in the corrugation direction without the risk of an inherently inflexible electrode layer tearing. Suitable polyurethane classes are for example thermoplastic polyurethane elastomers and polyurethane cast elastomers.

The term “one-piece” should be understood to mean in particular that the elastomer layer has not been joined together from a plurality of individual parts, at least along its two-dimensional extent, even if this joining together is by means of an adhesive bond. There are no transitions within the material at which material properties such as elasticity modulus, rigidity and the like vary.

“Corrugated” should be understood to mean a corrugated cross-sectional profile comprising a regular or irregular sequence of ridges and furrows. A regular sequence is preferred here.

An example of a corrugated profile in an elastomer layer having a through-thickness direction, a longitudinal direction and a transverse direction is when the corrugated profile is formed in the longitudinal direction.

According to an advantageous embodiment of the invention the first and the second side of the dielectric elastomer layer are corrugated in the same direction as each other. In a corrugated layer “corrugated in the same direction” means that ridges in the layer on the upper side (first side) correspond to corresponding furrows in the layer on the lower side (second side) and furrows in the layer on the upper side correspond to corresponding ridges in the layer on the lower side. To that extent in the case of a corrugated cross-sectional profile the film thickness of the layer corrugated in the same direction can be constant. Such a same-directional corrugation structure is advantageous in particular when the corrugation amplitude, i.e. the difference in height between ridges and furrows, is approximately in the range of the overall film thickness. If conversely the corrugation amplitude is very much smaller than the overall film thickness, good extensibility is achieved even without same-directional corrugation.

The dielectric elastomer can for example have a maximum stress of ≧0.2 MPa and a maximum extension of ≧100%. In the extension range up to ≦200% the stress can be from ≧0.1 MPa to ≦50 MPa (determined in accordance with ASTM D 412). With an extension of 100% the elastomer can moreover have an elasticity modulus of ≧0.1 MPa to ≦100 MPa (determined in accordance with ASTM D 412).

It is possible for the elastomer layer to have a compact structure. Within the context of the present invention this is understood to mean that the proportion of voids within the individual layers is ≧0 vol. % to ≦5 vol. % and in particular ≧0 vol. % to ≦1 vol. %.

According to the invention the electrodes have a corrugated design corresponding to the first and second side of the dielectric elastomer layer. This means that they follow the corrugation of the first and second side of the dielectric elastomer layer. The electrodes can furthermore be structured. A structured electrode can be designed for example as a conductive coating in stripes or in the form of a lattice. The sensitivity of the electromechanical converter can additionally be influenced in this way and adapted to specific applications. Thus the electrodes can be structured in such a way that the converter has active and passive regions. In particular the electrodes can be structured in such a way that signals can be detected locally or active regions can be selectively controlled. This can be achieved in that the active regions are provided with electrodes whereas the passive regions have no electrodes.

The thickness of the dielectric elastomer layer can be in a range for example from ≧10 μm to ≦500 μm and preferably ≧20 μm to ≦200 μm. The film thickness of the first and/or second electrode can be in a range for example from ≧0.01 μm to ≦50 μm and preferably ≧0.03 μm to ≦20 μm.

Details of the composition of the polyurethane elastomers are disclosed in the yet unpublished European patent application 10192847.1 which is fully incorporated by reference. In the course of the present invention it was found that such polyurethane polymers show good elastomcric properties and can be suited as dielectric elastomers in electromechanical actor systems. In particular a high maximum extension is advantageous.

The polyurethane polymer comprised in the dielectric elastomer layer can preferably have a maximum stress of ≧0.2 MPa, in particular 0.4 MPa to 50 MPa, and a maximum extension of ≧100%, in particular ≧120%. In the extension range up to ≦200% the polyurethane can moreover have a stress of 0.1 MPa to 50 MPa, for example 0.5 MPa to 40 MPa, in particular 1 MPa to 30 MPa (determined in accordance with ASTM D 412). Furthermore the polyurethane can have an elasticity modulus at an extension of 100% of 0.1 MPa to 100 MPa, for example 1 MPa to 80 MPa (determined in accordance with ASTM D 412).

The polyurethane polymer is preferably a dielectric elastomer having an electrical volume resistivity in accordance with ASTM D 257 of ≧10¹² to ≦10¹⁷ Ohm cm. It is moreover possible for the polyurethane polymer to have a dielectric disruptive strength in accordance with ASTM 149-97a of ≧50 V/μm to ≦200 V/μm.

Fillers can regulate the dielectric constant of the elastomer layer, for example. The polyurethane polymer preferably includes fillers to increase the dielectric constant such as fillers having a high dielectric constant. Examples thereof are ceramic fillers, in particular barium titanate, titanium dioxide and piezoelectric ceramics such as quartz or lead zirconium titanate, as well as organic fillers, in particular those having a high electrical polarising capacity, for example phthalocyanines.

A high dielectric constant can also be achieved by the introduction of electrically conductive fillers below the percolation threshold. Examples are carbon black, graphite, single-walled or multi-walled carbon nanotubes, electrically conductive polymers such as polythiophenes, polyanilines or polypyrroles, or mixtures thereof. Carbon black types which exhibit surface passivation and which thus in low concentrations increase the dielectric constant below the percolation threshold yet do not lead to an increase in the conductivity of the polymer are of particular interest in this context.

In a further embodiment of the electromechanical converter according to the invention the material of the dielectric elastomer layer has a dielectric constant ∈ᵣ of ≧2 This dielectric constant can also be in a range from ≧2 to ≦10000 or from ≧3 to ≦1000. This constant can be determined in accordance with ASTM 150-98.

In a further embodiment of the electromechanical converter according to the invention the material of the first electrode and/or the second electrode is selected from the group comprising metals, metal alloys, conductive oligomers or polymers, conductive oxides and/or polymers filled with conductive fillers. Polythiophenes, polyanilines or polypyrroles, for example, can be used as conductive oligomers or polymers. Metals, conductive carbon-based materials, such as carbon black, carbon nanotubes (CNT) or conductive oligomers or polymers, for example, can be used as fillers for polymers filled with conductive fillers. The filler content of the polymers here is preferably above the percolation threshold, such that the conductive fillers continuously form electrically conductive paths within the polymers filled with conductive fillers.

In a further embodiment of the electromechanical converter according to the invention the thickness ratio of the dielectric elastomer layer to the first and/or second electrode is in a range from ≧1:5 to ≦50000:1. The thickness ratios are given in each case for the thickness of the elastomer layer and one electrode and can also be in a range from ≧100:1 to ≦250:1.

In a further embodiment of the electromechanical converter according to the invention the first and the second side of the dielectric elastomer layer are designed with sinusoidal corrugation, triangular corrugation or rectangular corrugation. It is favourable if the corrugated cross-sectional profile of the dielectric elastomer layer is a sine wave profile or a triangle wave profile. These wave shapes are to be understood here to mean that sine or triangle waves scaled to any height and/or width can be used. However, sine waves obeying the relation y=Asin(Bx) and triangle waves in which the vertex of the triangle forms a right angle are preferred.

In a further embodiment of the electromechanical converter according to the invention the wavelength of the corrugated first and second side of the dielectric elastomer layer is in a range from ≧1 μm to ≦5000 μm. The wavelength should be understood here in particular to be the distance from one ridge to the adjacent ridge and can preferably be ≧5 μm to ≦2000 μm.

In a further embodiment of the electromechanical converter according to the invention the corrugation amplitude of the corrugated first and second side of the dielectric elastomer layer is in a range from ≧0.3 μm to ≦5000 μm. The corrugation amplitude should be understood here to be the vertical distance between the lowest point of a furrow and the highest point of an adjacent ridge and can preferably be ≧5 μm to ≦2000 μm.

The present invention also relates to a method for producing an electromechanical converter according to the invention comprising the following steps:

(a1) provision of a dielectric elastomer layer designed as one piece and having a first side and a second side opposite the first side,
the first and the second side of the dielectric elastomer layer being corrugated in the same direction as each other with the formation of ridges and furrows and
the dielectric elastomer layer comprising a polyurethane polymer; and
(b1) bringing the first side of the dielectric elastomer layer into contact with a first electrode and bringing the second side of the dielectric elastomer layer into contact with a second electrode,
the contact being established in such a way that the first and second electrodes have a corrugated design corresponding to the first and second side of the dielectric elastomer layer.

The dielectric elastomer layer can be brought into contact with the electrodes directly from a roll, for example, thereby making a roll-to-roll process possible.

The electrodes can be applied to the dielectric elastomer layer by means of conventional methods such as sputtering, spraying, vacuum deposition, chemical vapour deposition (CVD), printing, knife application and spin coating.

Alternatively, solvent-based or extrusion and coextrusion methods can also be used in the aforementioned steps. A further possibility is lamination at elevated temperatures. A permanent bond between the individual layers can be established in this way.

In one embodiment of the method according to the invention the provision of the dielectric elastomer layer in step (a1) takes place by means of blow moulding, extrusion, reaction extrusion or reaction injection moulding. Corrugated nozzles or other tools can be used here to obtain a corrugated elastomer layer. It is furthermore possible for smooth nozzles moving in cycles to create the corrugated shape of the elastomer layer. The corrugations can be formed perpendicular (in the case of oscillating nozzles) or parallel to the direction of flow of the elastomer during this step.

The present invention also provides the use of an electromechanical converter according to the invention as an actuator, sensor or generator. The use can take place in the electromechanical and/or electroacoustical area, for example. In particular, electromechanical converters according to the invention can be used in the area of energy recovery from mechanical vibrations (known as energy harvesting), acoustics, ultrasound, medical diagnostics, acoustic microscopy, mechanical sensors, in particular pressure, force and/or strain sensors, robotics and/or communication technology, in particular in loudspeakers, vibration converters, light deflectors, membranes, modulators for glass fibre optics, pyroelectric detectors, capacitors and control systems.

The present invention likewise relates to an actuator, sensor or generator comprising an electromechanical converter according to the invention. To avoid unnecessarily lengthy descriptions, reference is made to the above embodiments of the converter in regard to details and special embodiments.

The invention is described in more detail by reference to the FIGURE below, without being restricted thereto.

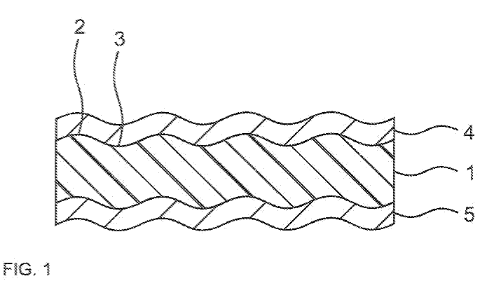

FIG. 1 shows an electromechanical converter.

FIG. 1 shows a cross-sectional view of an electromechanical converter. This can be the cross-sectional view of a laminate film. The through-thickness direction of this arrangement runs vertically in the drawing and the longitudinal direction horizontally.

A dielectric elastomer layer 1 has a same-directional corrugated design. Ridges 2 on the upper side (first side) correspond here to corresponding furrows on the lower side (second side) and furrows 3 to corresponding ridges on the lower side. To that extent in the case of a corrugated cross-sectional profile the film thickness of the elastomer layer 1 is constant. The dielectric elastomer layer 1 is furthermore designed as one piece. It is thus in particular not a laminate of a plurality of elastomer layers.

The dielectric elastomer layer 1 is in contact on its upper side with a first electrode 4. The second electrode 5 is on the lower side of the dielectric elastomer layer 1. Regarding the design of the electrodes the first and second electrodes (4, 5) have a corrugated design corresponding to the first and second side of the dielectric elastomer layer (1). The film thickness of the first and second electrode (4, 5) in the corrugated cross-sectional profile shown is thus also constant. The cross-sectional profile of the entire converter has been optimised to the thickness behaviour under extension.

1. Electromechanical converter,
characterised in that
the converter comprises a dielectric elastomer layer (1) designed as one piece and having a first side and a second side opposite the first side,
the first and the second side of the dielectric elastomer layer (1) having a corrugated design with the formation of ridges (2) and furrows (3),
the dielectric elastomer layer (1) comprising a polyurethane polymer,
the first side of the dielectric elastomer layer (1) being in contact with a first electrode (4) and the second side of the dielectric elastomer layer (1) being in contact with a second electrode (5) and
the first and second electrode (4, 5) having a corrugated design corresponding to the first and second side of the dielectric elastomer layer (1).

2. Electromechanical converter according to claim 1,
characterised in that
the first and the second side of the dielectric elastomer layer (1) are corrugated in the same direction as each other.

3. Electromechanical converter according to claim 1 or 2,
characterised in that
the material of the dielectric elastomer layer (1) has a dielectric constant ∈ᵣ of ≧2.

4. Electromechanical converter according to one of claims 1 to 3,
characterised in that
the material of the first electrode (4) and/or the second electrode (5) is selected from the group comprising metals, metal alloys, conductive oligomers or polymers, conductive oxides and/or polymers filled with conductive tillers.

5. Electromechanical converter according to one of claims 1 to 4,
characterised in that
the thickness ratio of the dielectric elastomer layer (1) to the first and/or second electrode (4, 5) is in a range from ≧1:5 to ≦50000:1.

6. Electromechanical converter according to one of claims 1 to 5,
characterised in that
the first and the second side of the dielectric elastomer layer (1) are designed with sinusoidal corrugation, triangular corrugation or rectangular corrugation.

7. Electromechanical converter according to one of claims 1 to 6,
characterised in that
the wavelength of the corrugated first and second side of the dielectric elastomer layer (1) is in a range from ≧1 μm to ≦5000 μm.

8. Electromechanical converter according to one of claims 1 to 78,
characterised in that
the corrugation amplitude of the corrugated first and second side of the dielectric elastomer layer (1) is in a range from ≧0.3 μm to ≦5000 μm.

9. Method for producing an electromechanical converter according to one of claims 1 to 8, comprising the following steps:
(a1) provision of a dielectric elastomer layer (1) designed as one piece and having a first side and a second side opposite the first side,
the first and the second side of the dielectric elastomer layer (1) having a corrugated design with the formation of ridges (2) and furrows (3) and
the dielectric elastomer layer (1) comprising a polyurethane polymer; and
(b1) bringing the first side of the dielectric elastomer layer (1) into contact with a first electrode (4) and bringing the second side of the dielectric elastomer layer (1) into contact with a second electrode (5),
the contact being established in such a way that the first and second electrodes (4, 5) have a corrugated design corresponding to the first and second side of the dielectric elastomer layer (1).

10. Method according to claim 9,
characterised in that
the provision of the dielectric elastomer layer (1) in step (a1) takes place by means of blow moulding, extrusion, reaction extrusion or reaction injection moulding.

11. Use of an electromechanical converter according to one of claims 1 to 8 as an actuator, sensor or generator.

12. Actuator, sensor or generator comprising an electromechanical converter according to one of claims 1 to 8.
